(19) United States
(12) Patent Application Publication
(10) Pub. No.: US 2009/0204270 A1
(43) Pub. Date: Aug. 13, 2009

(54) METHOD AND SYSTEM FOR REDUNDANT MANAGEMENT OF FANS WITHIN A SHARED ENCLOSURE

(75) Inventor: Enrique Q. Garcia, Tucson, AZ (US)

Correspondence Address: CANTOR COLBURN LLP - IBM TUSCON DIVISION, 20 Church Street, 22nd Floor, Hartford, CT, 06103, US

(73) Assignee: INTERNATIONAL BUSINESS MACHINES CORPORATION, Armonk, NY (US)

(21) Appl. No.: 12/030,458

(22) Filed: Feb. 13, 2008

(51) Int. Cl. G05D 23/00; H05K 7/20

(52) U.S. Cl. 700/300; 361/695

(57) ABSTRACT

A method for providing redundant management of fans within a shared enclosure, comprising: detecting for an abnormal cooling condition in an enclosure configured for housing a first server having a first fan and a second server having a second fan; operating the first fan and the second fan to run at a nominal power state; and enabling the first server to assert the first fan to operate from the nominal power state to the high power state while enabling the first server to unconditionally force the second fan of the second server to operate from the nominal power state to a high power state through an overriding mechanism in the second server when the abnormal cooling condition is detected in the enclosure, the overriding mechanism being coupled to the first server.

### BACKGROUND OF THE INVENTION

1. Field of the Invention

This invention relates to a management system, and particularly to a system for redundant management of fans within a shared enclosure.

2. Description of Background

In highly integrated and redundant computing systems, such as the DS9000 disk storage subsystem, multiple servers share a common enclosure along with input and output (I/O) devices. Within such a common enclosure both the power and cooling fans are also shared. Typically, power is always active and distributed via one or more backplane power rails with servers and I/O devices being hot plugged onto the power rail(s). Servers and I/O devices independently have both a standby power state and a fully powered on state.

When input power is first applied to the system, or when a server or I/O device is hot plugged, the servers and I/O devices independently power up the standby power state and, later when directed, continue to the fully powered on state. When all servers and I/O devices are in the standby power state the system consumes very little power and all fans must be turned off primarily for conservation and aesthetic reasons (e.g., no fan noise). Under normal conditionals, when any entity in the system is not in the standby power state, all fans must run at a nominal speed to assure adequate cooling of all shared resources. Also under normal conditions, each server, as a matter of practicality, directly manages a subset of all the enclosure fans. For example, server 1 manages fan 1, server 2 manages fan 2, server 3 manages fan 3, and so forth, in which all the servers and fans share a common enclosure. In the event of an abnormal cooling condition detected anywhere in the system (e.g., over temperature, fan failure, etc.) all fans must be forced to run at a high speed in order to compensate for the anomaly.

### SUMMARY OF THE INVENTION

The shortcomings of the prior art are overcome and additional advantages are provided through the provision of a method for providing redundant management of fans within a shared enclosure, the method comprising: detecting for an abnormal cooling condition in an enclosure configured for housing a first server having a first fan and a second server having a second fan; operating the first fan and the second fan to run at a nominal power state; and enabling the first server to assert the first fan to operate from the nominal power state to the high power state while enabling the first server to unconditionally force the second fan of the second server to operate from the nominal power state to a high power state through an overriding mechanism in the second server when the abnormal cooling condition is detected in the enclosure, the overriding mechanism being coupled to the first server.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### TECHNICAL EFFECTS

As a result of the summarized invention, technically we have achieved a solution for providing redundant management of fans within a shared enclosure.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 is a simplified schematic diagram illustrating the basic elements of an integrated management system in accordance with one exemplary embodiment of the present invention;

FIG. 2 is a simplified schematic diagram illustrating the topology of a first server and a second server disposed in an enclosure in accordance with one exemplary embodiment of the present invention;

FIG. 3 is a schematic diagram illustrating a literal equivalence circuit of the first server in accordance with one exemplary embodiment of the present invention; and

FIG. 4 is a flow diagram illustrating exemplary method for providing redundant management of fans within a shared enclosure.

The detailed description explains the preferred embodiments of the invention, together with advantages and features, by way of example with reference to the drawings.

### DETAILED DESCRIPTION OF THE INVENTION

The present invention and the various features and advantageous details thereof are explained more fully with reference to the non-limiting embodiments that are illustrated in the accompanying drawings and detailed in the following description. It should be noted that the features illustrated in the drawings are not necessarily drawn to scale. Descriptions of well-known or conventional components and processing techniques are omitted so as to not necessarily obscure the present invention in detail. The examples used herein are intended merely to facilitate an understanding of ways in which the invention may be practiced and to further enable those of skill in the art to practice the invention. Accordingly, the examples should not be construed as limiting the scope of the invention.

The inventors herein have recognized a system for implementing a technique for positively and redundantly managing shared fans from multiple servers even when one server has failed. More specifically, the inventors herein have recognized a system implementing a technique for detecting the power state of server(s) and I/O device(s) within a shared enclosure and providing a mechanism for a server to unconditionally force fans managed by another server to a high powered state when an abnormal cooling condition is detected, even if the other server is inoperative or powered off.

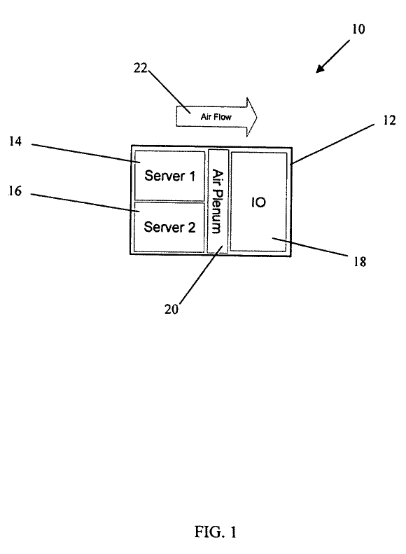

Now referring to the drawings, FIG. 1 is a simplified schematic illustrating the basic elements of an integrated management system 10 configured for managing fans within a shared enclosure in accordance with one exemplary embodiment of the present invention. The system 10 includes an enclosure 12, a first server 14, a second server 16, and an I/O device 18. In accordance with one embodiment, an air plenum 20 is formed within the enclosure 12 to facilitate the circulation of air within the enclosure 12, and more particularly, to direct air to flow from the servers (14, 16) to the I/O device 18 forming an air flow path, which is indicated by arrow 22. Of course, the system 10 may be extended to include additional servers, I/O devices, and other shared entities; however, for simplistic purposes only two servers and a shared I/O device being housed in a shared enclosure is discussed in detail.

The enclosure 12 can be any conventional device for supporting or housing the first server 14, second server 16, and I/O device 18 therein. The enclosure 12 can be mounted on a rack-mountable chassis with other enclosures of a main frame in accordance with one exemplary embodiment. The enclosure 12 can be of any size or made of any suitable material (e.g., aluminum) depending on the application.

The first server 14, second server 16, and I/O device 18 can each be disposed within the enclosure 12 by inserting the same into mountable racks formed therein in accordance with one non-limiting exemplary embodiment. In accordance with another non-limiting exemplary embodiment, the first server 14, second server 16, and I/O device 18 can be attached to corresponding walls of the enclosure using one or more securing means (e.g., fastener), in a configuration, for example, as shown in FIG. 1. Of course, the servers (14, 16), I/O device 18, and other shared entities can be housed within the enclosure 12 in various configurations and should not be limited to the example(s) described above.

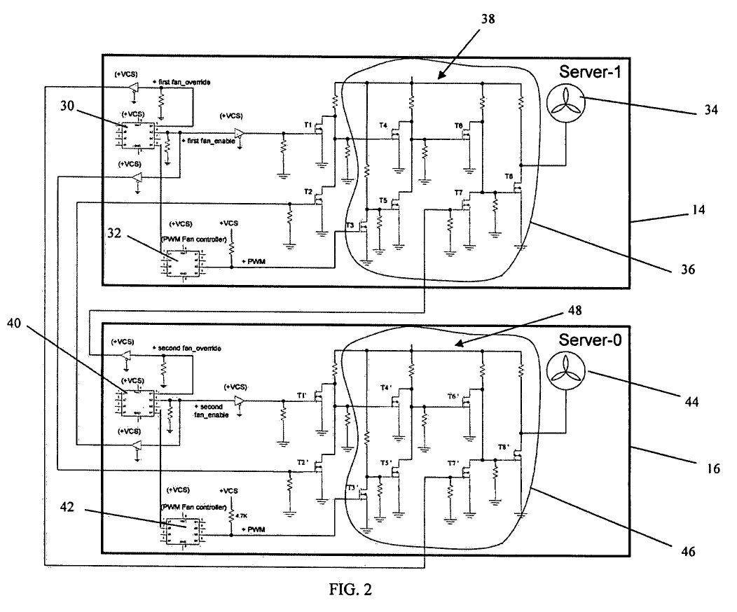

Now turning to the topology of each server, FIG. 2 illustrates the basic elements of the first server 14 and the second server 16. The first server 14 includes a first service microprocessor 30, a first fan controller 32, transistor devices T1-T8, and a first fan 34. In one embodiment, transistor devices T3-T8 of the first server 14 make up a fan control transistor network 36 (low-level transistor circuit), which is fully redundant. In other words, each additional server housed within the enclosure will also comprise of a corresponding fan control transistor network. The first server 14 further includes a power rail 38, which provides power to the first fan 34 and the fan control transistor network 36 of the first server 14 in accordance to one embodiment. In one embodiment, the fan control transistor network 36 of the first server 14 is always powered on by the power rail 38 and the powered-on state of the fan control transistor network 36 of the first server 14 is independent of the state of the first server 14.

The second server 16 being a mirror image of the first server includes a second service microprocessor 40, a second fan controller 42, transistor devices T1′-T8′, and a second fan 44. In one embodiment, transistor devices T3′-T8′ of the second server 16 make up a fan control transistor network 46 (low-level transistor circuit), which is fully redundant. The second server 16 further includes a power rail 48, which provides power to the second fan 44 and the fan control transistor network 46 of the second server 16 in accordance to one embodiment. In one embodiment, the fan control transistor network 46 of the second server 16 is always powered on by power rail 48 and the powered-on state of the second fan control transistor network 46 of the second server 16 is independent of the state of the second server 16.

In accordance with one embodiment, the first service microprocessor 30 and the second microprocessor 40 are each in signal communication with a corresponding main processor (not shown), which correspondingly powers the same accordingly. The main processor respectively for each service microprocessor (30, 40) enables each service microprocessor (30, 40) to be independently fully powered on or fully powered off.

The first service microprocessors 30 and the second service microprocessor 40 correspondingly of the first server 14 and the second server 16 can each be any conventional microprocessor configured for carrying out the methods and/or functions described herein. In one exemplary embodiment, the first service microprocessor 30 and the second microprocessor 40 each comprises a combination of hardware and/or software/firmware with a computer program that, when loaded and executed, permits the first service microprocessor 30 and the second microprocessor 40 to operate such that it carries out the methods described herein. The first service microprocessor 30 and the second microprocessor 40 are each configured for directly managing the main power and the fan operational states of the first server 14 and second server 16 respectively.

Computer program means or computer program used in the present context of exemplary embodiments of the present invention include any expression, in any language, code, notation, or the like of a set of instructions intended to cause a system having information processing capabilities to perform a particular function either directly or after conversion to another language, code, notation, or the like reproduction in a different material form.

The first fan controller 32 of the first server 14 is coupled to the first service microprocessor 30 and is configured for controlling the first fan 34 in accordance with one exemplary embodiment. More specifically, the first fan controller 32, under the control of the first service microprocessor 30, controls the speed of the first fan 34 by using pulse width modulation (PWM). The first fan controller 32 generates a PWM fan controller signal (+PWM) for controlling the speed of the first fan 34. The faster the PWM fan controller signal (+PWM) from the first fan controller 32 is pulsed to the first fan 34, the faster the first fan 34 runs. If the PWM fan controller signal (+PWM) from the first fan controller 32 is held solidly asserted, the first fan 34 will run at a maximum speed or the first fan 34 will be at a high-powered state.

The second fan controller 42 of the second server 16 is coupled to the second service microprocessor 40 and is configured for controlling the second fan 44 in accordance with one exemplary embodiment. More specifically, the second fan 44, under the control of the second service microprocessor 40, controls the speed of the second fan 44 by using PWM. The second fan controller 32 generates a PWM fan controller signal (+PWM) for controlling the speed of the second fan 44. Similarly, the faster the PWM fan controller signal (+PWM) from the second fan controller 32 is pulsed to the second fan 44, the faster the second fan 44 runs. If the PWM fan controller signal (+PWM) from the second fan controller 42 is held solidly asserted, the second fan 44 will run at a maximum speed or the second fan 44 will be at a high-powered state. As such, the fan controllers (32, 42) operate and are configured similarly as shown in FIG. 2.

In accordance with one exemplary embodiment, the first service microprocessor 30 of the first server 14 is configured for generating a first fan enable signal (first fan_enable) for enabling the first fan 34 to operate at a nominal cooling speed based on PWM and further for enabling the opposite fan (the second fan 44) to also operate at a nominal cooling speed based on PWM via transistor T2′. The first service microprocessor 30 generates the first fan enable signal when the first server 14 is fully powered on under the control of its corresponding main processor. In other words, the first service microprocessor 30 is directed to change the power state of the first server 14 from a standby state or a low-powered state to a fully powered-on state or nominal power state by its corresponding main processor. As such, when the main processor of the first server 14 is powered off, the first service microprocessor 30 places the first server 14 in standby or an idle state and when the main processor of the first server 14 is powered on, the first service microprocessor 30 places the first server 14 in a fully powered-on state. The first service microprocessor asserts the first fan enable signal to both the fan control transistor network 36 of the first server 14 and the fan control transistor network 46 of the second server 16 via the backplane when the power state of the first server 14 changes from standby to the fully powered-on state in accordance with one exemplary embodiment.

In accordance with one exemplary embodiment, the second service microprocessor 40 of the second server 16 is configured for generating a second fan enable signal (second fan_enable) for enabling the second fan 44 to operate at a nominal cooling speed based on PWM and further for enabling the opposite fan (the first fan 34) to also operate at a nominal cooling speed based on PWM via transistor T2. The second service microprocessor 40 generates the second fan enable signal when the second server 14 is fully powered on under the control of its corresponding main processor. In other words, the second service microprocessor 40 is directed to change the power state of the first server 16 from a standby state to a fully powered-on state by its corresponding main processor. As such, when the main processor of the second server 16 is powered off, the second service microprocessor 40 places the second server 16 in standby and when the main processor of the second server 16 is powered on, the second service microprocessor 40 places the second server 16 in a fully powered-on state. The second service microprocessor asserts the second fan enable signal to both the fan control transistor network 46 of the second server 16 and the fan control transistor network 36 of the first server 14 via the backplane when the power state of the second server 14 changes from standby to the fully powered-on state in accordance with one exemplary embodiment.

In accordance with one exemplary embodiment, the effective logic of each of the fan control transistor networks (36,46) is to disable the PWM fan controller signal of one of the servers (14, 16) if neither server is in the fully powered on state (i.e., if neither the first fan enable signal or the second fan enable signal is asserted). Thus, the first fan 34 and the second fan 44 will be turned off because the PWM fan controller signals are de-gated In other words, neither server (14, 16) asserts its corresponding fan enable signal when neither server (14, 16) is in the fully powered on state forming a system standby state. During a system standby state, all elements (e.g., servers) are in the standby power state and all fans are off. It is contemplated that each of the fan control transistor networks (36, 46) can be expanded to include fan enable signals from any number of servers or other I/O devices in accordance with exemplary embodiments of the present invention.

In accordance with one exemplary embodiment fan control transistor network 36 of the first server 14 provides a fully independent and direct mechanism to override and solidly assert the PWM fan controller signal to the second fan 44 on the second server 16, which has the effect of forcing the second fan 44 to run at a high speed or be in a high powered state. Similarly, the fan control transistor network 46 of the second server 14 also provides a fully independent and direct mechanism to override and solidly assert the PWM fan controller signal to the first fan 34 on the first server 14, which has the effect of forcing the first fan 34 to run at a high speed or be in a high powered state. This allows one server to unconditionally force the fan on the other server to high speed regardless of the state of that server.

In accordance with one exemplary embodiment, the first service microprocessor 30 is further configured for speeding up the first fan 34 and simultaneously asserting a first fan-overriding signal (first fan_override) to the fan control transistor network 46 on the second server 16, which unconditionally forces the second fan 44 of the second server 16 to high speed, when an abnormal cooling condition is detected. Similarly, the second service microprocessor 40 is further configured for speeding up the second fan 44 and simultaneously asserting a second fan-overriding signal (second fan_override) to the fan control transistor network 36 on the first server 14, which unconditionally forces the first fan 24 of the first server to high speed, when an abnormal cooling condition is detected. In accordance with one non-limiting embodiment, one or more sensors (not shown) are disposed within the enclosure 12 and are in signal communication with the first service microprocessor 30 and second service microprocessor 42 for measuring the temperature within the enclosure 12.

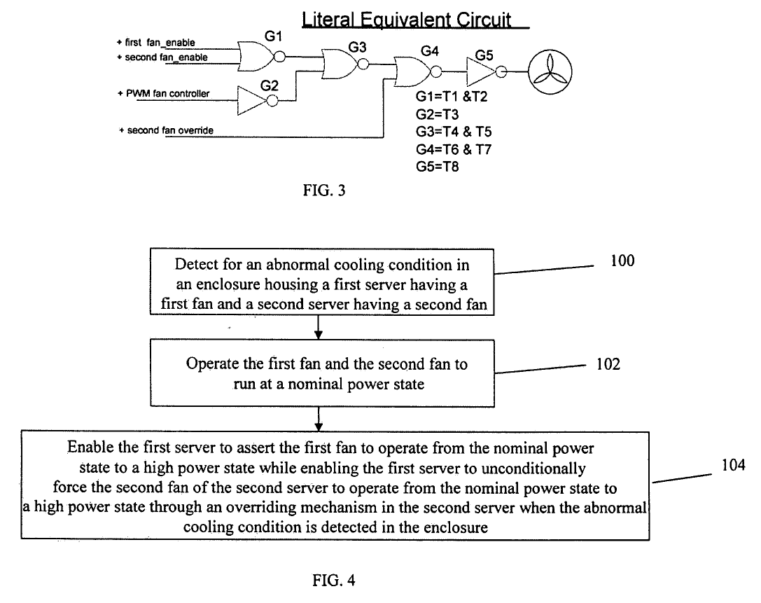

FIG. 3 is a schematic illustrating the literal equivalence circuit of each server shown in FIG. 2 to better understand how each fan (34, 44) is managed. For ease of discussion, the literal equivalence circuit for the first server 14 is shown. However, it should be understood that the literal equivalence circuit for the second server 16 is similar. As shown, gate 1 comprises of transistors T1 and T2. Gate 1 is a logical NOR gate that receives the first fan enable signal and the second fan enable signal as its inputs. Gate 2 comprises of transistor T3. Gate 2 is a logical NOT gate that receives the PWM fan controller signal (+PWM) signal from the first fan controller 32 as its inputs. Gate 3 comprises of the transistor T4 and T5. Gate 3 is a logical NOR gate that receives the output of gate 1 and gate 2. Gate 4 comprises transistors T6 and T7. Gate 4 is a logical NOR gate that receives the output of gate 3 and the second fan-overriding signal from the second server 16. Gate 5 comprises transistor T8. Gate 5 is a logical NOT gate that receives the output of gate 4. The output of gate 5 controls the operation of the first fan 34 based on the various signals from each gate.

In accordance with an exemplary embodiment of the present invention, an exemplary method for providing redundant management of fans within a shared enclosure is provided and illustrated in FIG. 4. In this exemplary method, detect for an abnormal cooling condition in an enclosure housing a first server having a first fan and a second server having a second fan in block 100. In accordance with one exemplary embodiment, one or more sensors are disposed within the enclosure for sensing for the abnormal cooling condition. Next, operate the first fan and the second fan to run at a nominal power state in block 102. In block 104, enable the first server to assert the first fan to operate from the nominal power state to a high power state while enabling the first server to unconditionally force the second fan of the second server to operate from the nominal power state to the high power state through an overriding mechanism in the second server when the abnormal cooling condition is detected in the enclosure. The overriding mechanism is coupled to the first server in accordance with one exemplary embodiment.

It should be understood that this concept can be extended to override fans located on additional servers, I/O devices, or other shared entities.

The capabilities of the present invention can be implemented in software, firmware, hardware or some combination thereof.

As one example, one or more aspects of the present invention can be included in an article of manufacture (e.g., one or more computer program products) having, for instance, computer usable media. The media has embodied therein, for instance, computer readable program code means for providing and facilitating the capabilities of the present invention. The article of manufacture can be included as a part of a computer system or sold separately.

Additionally, at least one program storage device readable by a machine, tangibly embodying at least one program of instructions executable by the machine to perform the capabilities of the present invention can be provided.

The flow diagrams depicted herein are just examples. There may be many variations to these diagrams or the steps (or operations) described therein without departing from the spirit of the invention. For instance, the steps may be performed in a differing order, or steps may be added, deleted or modified. All of these variations are considered a part of the claimed invention.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

What is claimed is:

1. A method for providing redundant management of fans within a shared enclosure, comprising:
detecting for an abnormal cooling condition in an enclosure configured for housing a first server having a first fan and a second server having a second fan;
operating the first fan and the second fan to run at a nominal power state; and
enabling the first server to assert the first fan to operate from the nominal power state to the high power state while enabling the first server to unconditionally force the second fan of the second server to operate from the nominal power state to a high power state through an overriding mechanism in the second server when the abnormal cooling condition is detected in the enclosure, the overriding mechanism being coupled to the first server.

2. The method as in claim 1, further comprising:
detecting a low power state in the first server and the second server, and
placing the first fan and the second fan in an off state when a lower power state is detected in the first server and the second server.

3. The system as in claim 1, wherein the first fan and the second fan operate at the nominal power state when either the first fan is enabled by a first enable signal from the first server or the second fan is enabled by a second enable signal from the second server.

4. The system as in claim 1, wherein a plurality of sensors is disposed within the housing for detecting the abnormal cooling condition.

5. The system as in claim 1, wherein the overriding mechanism comprises a low-level transistor circuit.
